(19) United States
(12) Patent Application Publication
(10) Pub. No.: US 2014/0084326 A1
(43) Pub. Date: Mar. 27, 2014

(54) LIGHT-EMITTING DIODE AND MANUFACTURING METHOD THEREOF

(71) Applicant: ADVANCED OPTOELECTRONIC TECHNOLOGY, INC., Hsinchu Hsien 303 (TW)

(72) Inventors: LUNG-HSIN CHEN, Hsinchu (TW); WEN-LIANG TSENG, Hsinchu (TW)

(73) Assignee: ADVANCED OPTOELECTRONIC TECHNOLOGY, INC., Hsinchu Hsien 303 (TW)

(21) Appl. No.: 13/948,197

(22) Filed: Jul. 23, 2013

(30) Foreign Application Priority Data
Sep. 27, 2012 (CN) 2012103690048

(51) Int. Cl. H01L 33/62

(52) U.S. Cl. CPC H01L 33/62
USPC 257/99; 438/27

(57) ABSTRACT

A light-emitting diode includes a ceramic substrate, an electrode group setting on the substrate and co-fired with the ceramic substrate, an LED chip setting on the substrate and electrically connecting the electrode group. The electrode includes a first electrode and a second electrode spacing from the first electrode. The first electrode and the second electrode extend from a top surface of the substrate to a bottom surface of the substrate via side surfaces of the substrate. The light-emitting diode can be connected to a power source by the electrode group on the bottom surface of the substrate or by the electrode group on the side surfaces of the substrate.

### BACKGROUND

1. Technical Field

The present disclosure relates to a light-emitting diode (LED) and manufacturing method thereof, and particularly to an LED which has a ceramic substrate plated with copper circuit, wherein the LED can be used as a top view LED or a side view LED.

2. Description of Related Art

LED, light-emitting diode, is one of the most interested industries, recently. Development to nowadays, LED products already have advantages such as energy saving, electricity saving, high efficiency, short response time, extensive life span, mercury-free, and environmental protection benefit. Therefore, LED is considered as the best light source of new generation illumination. Due to the configuration limitation an ordinary light-emitting diode can be used as a top view LED only or a side view LED only which restricts the application of the LED. Furthermore, the substrate of the ordinary LED which is usually made of metal core printed circuit board (MCPCB) is bulky and cannot have a precise dimension and sufficient mechanical strength. Furthermore, a bonding force between copper circuit (copper foil) and the laminates of the MCPCB is not high enough.

In view of the above-mentioned problem, it is necessary to provide a light-emitting diode which can be adapted to various demands of light output, i.e., top view and side view. Furthermore, the substrate of the LED can be precise and have high mechanical strength and bonding force between a copper circuit and a base material of the substrate of the LED.

### BRIEF DESCRIPTION OF THE DRAWINGS

FIG. 1 is a cross-sectional view of step 1 of the manufacturing method of a light-emitting diode according to the present disclosure.

FIG. 2 is a cross-sectional view of step 2 of the manufacturing method of a light-emitting diode according to the present disclosure.

FIG. 3 is a top view of step 2 of the manufacturing method of a light-emitting diode according to the present disclosure.

FIG 4 is a cross-sectional view of step 3 of the manufacturing method of a light-emitting diode according to the present disclosure.

FIG. 5 is a top view of step 3 of the manufacturing method of a light-emitting diode according to the present disclosure.

FIG. 6 is a cross-sectional view of step 4 of the manufacturing method of a light-emitting diode according to the present disclosure.

FIG 7 is a top view of step 4 of the manufacturing method of a light-emitting diode according to the present disclosure.

FIG. 8 is a cross-sectional view of step 5 of the manufacturing method of a light-emitting diode according to the present disclosure.

FIG. 9 is a top view of step 5 of the manufacturing, method of a light-emitting diode according to the present disclosure.

FIG. 10 is a cross-sectional view of step 6 of the manufacturing method of a light-emitting diode according to the present disclosure.

FIG 11. is a top view of step 6 of the manufacturing method of a light-emitting diode according to the present disclosure.

FIG 12 is a cross-sectional view of step 7 of the manufacturing method of a light-emitting diode according to the present disclosure.

FIG 13 is a top view of step 7 of the manufacturing method of a light-emitting diode according to the present disclosure.

FIG. 14 is an illustration of a light-emitting diode obtained from the manufacturing method represented by FIGS. 1-13 according to the present disclosure.

### DETAILED DESCRIPTION

Embodiments will now be described in detail below with reference to the appended figures.

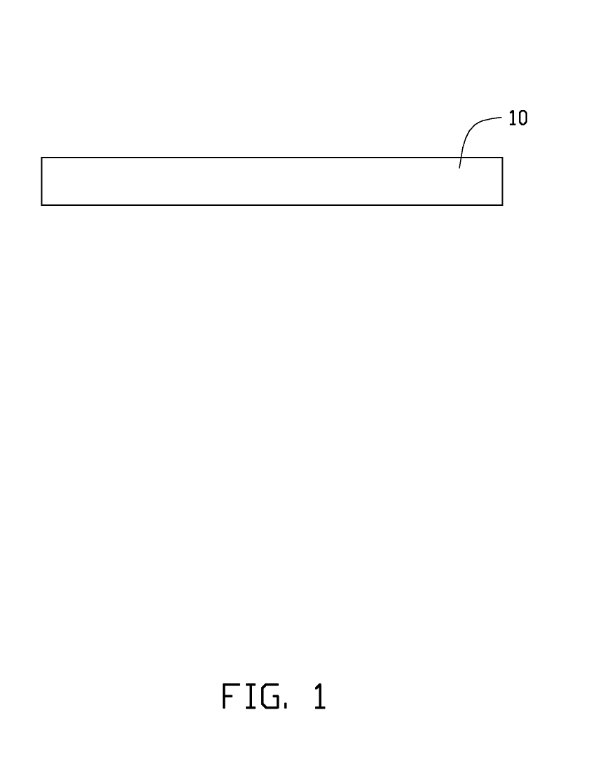

See FIGS. 1-13, the manufacturing method of light-emitting diode 100 of present disclosure mainly comprises the steps of:

Step 1: as shown in FIG. 1, it includes providing a substrate 10. The substrate 10 is made of alumina or alumina containing ceramic material. The substrate 10 is a rectangle plate, with a top surface and a bottom surface which are parallel to each other.

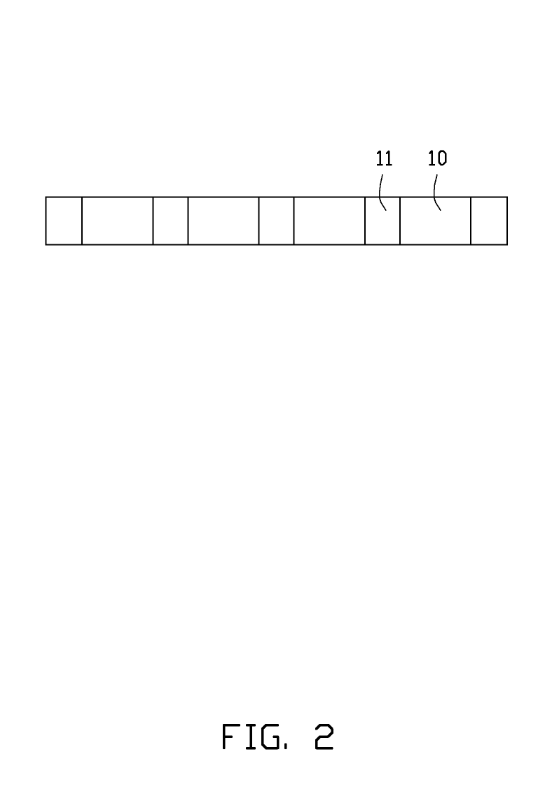

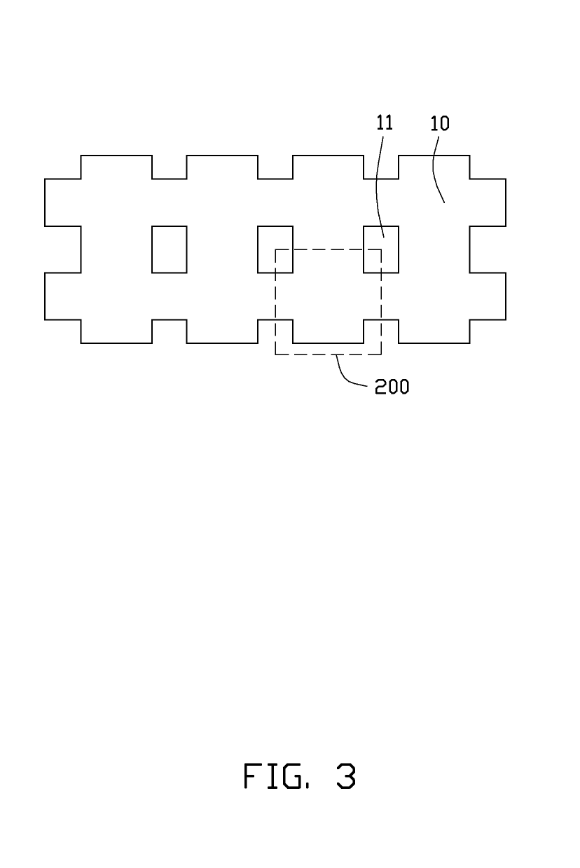

Step 2: as shown in FIGS. 2-3, it includes defining a plurality of via holes 11 in the substrate 10 which penetrate through the top surface and the bottom surface of the substrate 10. The pluralities of via holes 11 are equidistant and separately distributing at the peripheral part and middle part of the substrate 10. The substrate 10 is separated into a plurality of identical regions 200 wherein each region 200 is defined by four adjacent via holes 11 located at four corners of the region 200. In this embodiment, the cross-sectional area of each of the plurality of via holes 11 is rectangle. The middle part of the substrate 10 is defined with three via holes 11, and the width of each of the three via holes 11 is smaller than the distance of between two adjacent via holes 11.

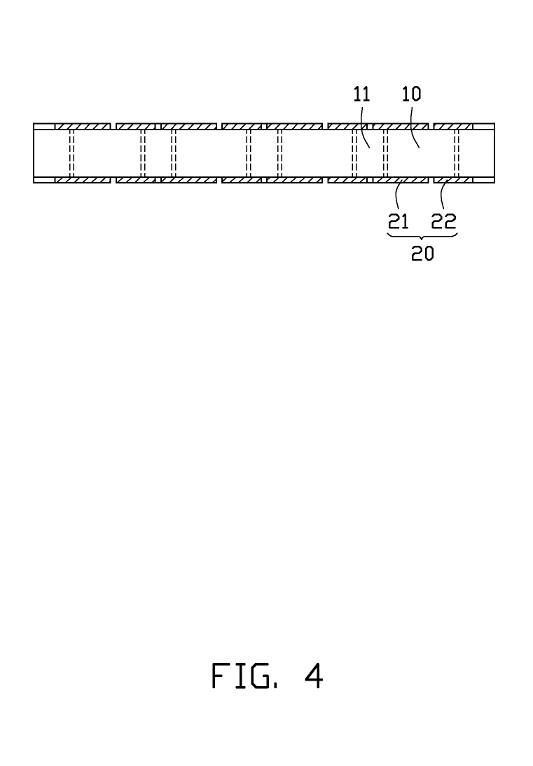

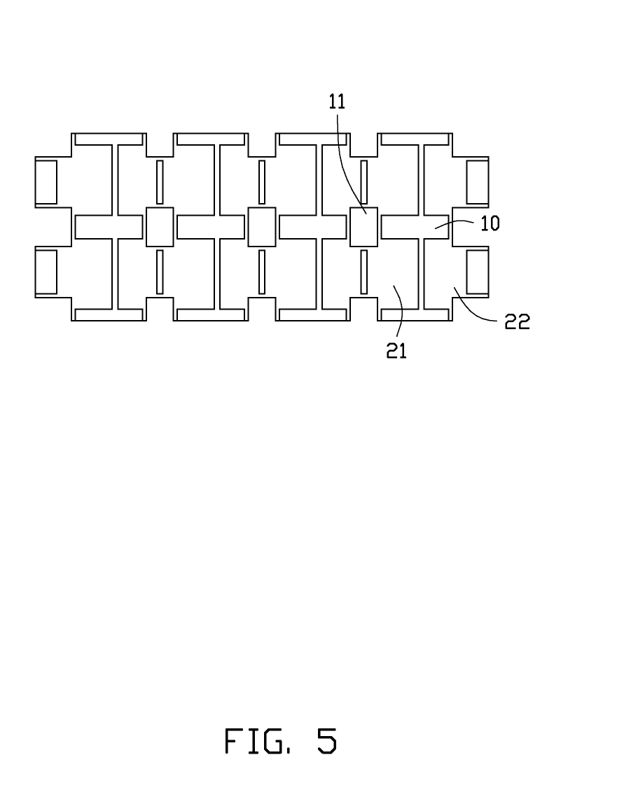

Step 3: as shown in FIGS. 4-5, it includes forming a plurality electrode groups 20 on the top surface, the bottom surface and in the via holes 11 of the substrate 10. Each electrode group 20 includes a first electrode 21 and a second electrode 22. The first electrode 21 and the second electrode 22 are deposed spacing from each other. Each region 200 has one electrode group 20. For each region 200, the first electrode 21 overlays over half of the top surface and over half of the bottom surface of the region 200 of the substrate 10. And the first electrode 21 also overlays on the partial inner surfaces of two of the four adjacent via holes 11 which defines the region 200, i.e. a first lateral side surface of the region 200, whereby the first electrode 21 extends from the top surface to the bottom surface through the two via holes 11 of the region 200 of the substrate 10. The second electrode 22 overlays the other part of the top/bottom surfaces of the region 200, which is less than a half of the top surface and the bottom surface of the region 200 of the substrate 10, and the second electrode 22 is on the top surface and bottom surface and is spaced from the first electrode 21. The second electrode 22 is similar to the first electrode 21, wherein it also overlays on the inner surfaces of the other two of the four via holes 11 which define the region 200, wherein the inner surfaces of the other two of the four via holes 11 constitute a second lateral side surface of the region 200, which is opposite to the first lateral side surface.

The method of forming the electrode groups 20 uses the method of directly plating copper on the ceramic substrate 10. Moreover, the electrode groups 20 and the substrate 10 which is in the form of a green ceramic tape are subjected to high temperature co-firing whereby the substrate 10 is solidified and the electrode groups 20 are very firmly connected to the co-fired substrate 10. Preferably, the electrode group 20 is formed by direct plate copper. The manufacturing method of the substrate 10 with the electrode groups 20 thereon achieves a miniaturized product with a high dimensional precision and mechanical strength. Furthermore, the bonding strength between the electrode groups 20 which are made of copper and the substrate 10 which is made of ceramic is very high due to the co-firing of the electrode groups 20 and the substrate 10.

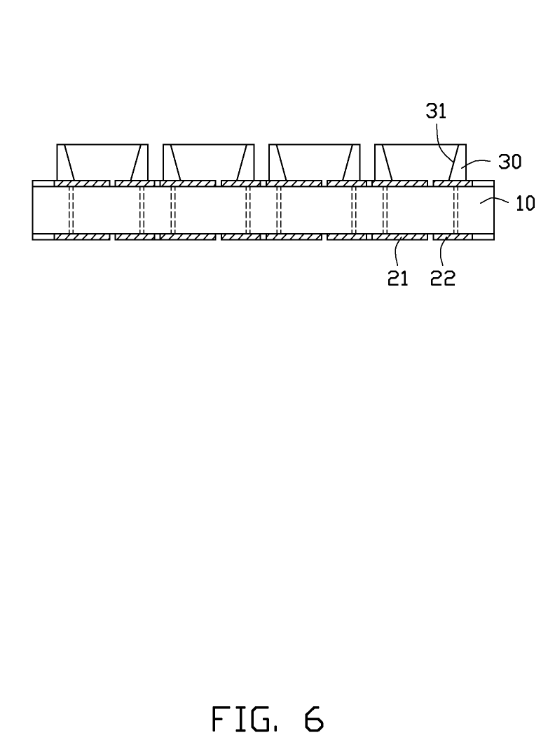

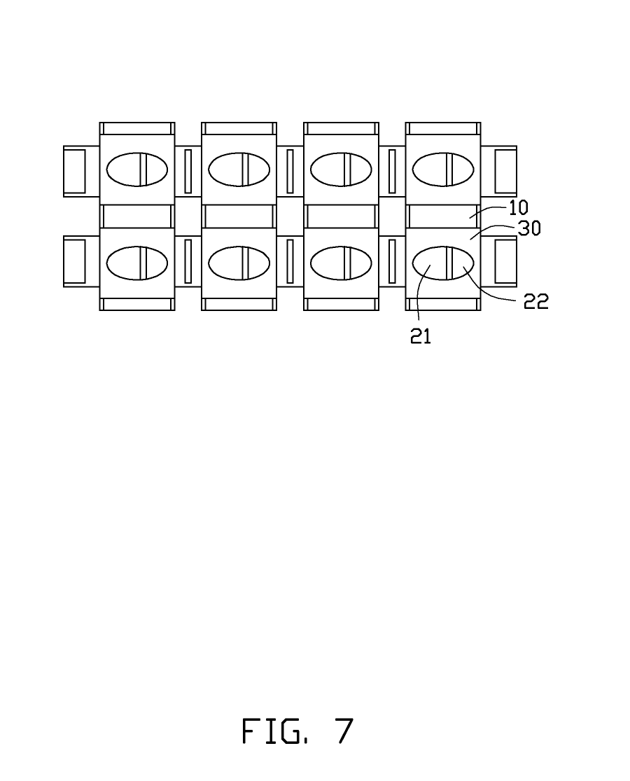

Step 4: as shown in FIGS. 6-7, it includes forming a reflective layer 30 on the substrate 10. On the substrate 10, each region 200 corresponds to a reflective layer 30. The reflective layer 30 is formed on the top surface of the substrate 10 by epoxy resin molding technique. Each reflective layer 30 forms a reflective cup 31. A part of the first electrode 21 and a part of the second electrode 22 are exposed by the bottom of the reflective cop 31. The epoxy resin material of the reflective layer 30 securely connects with the ceramic material of the substrate 10; therefore the mechanical strength of connection between the reflective layer 30 and the substrate 10 is improved.

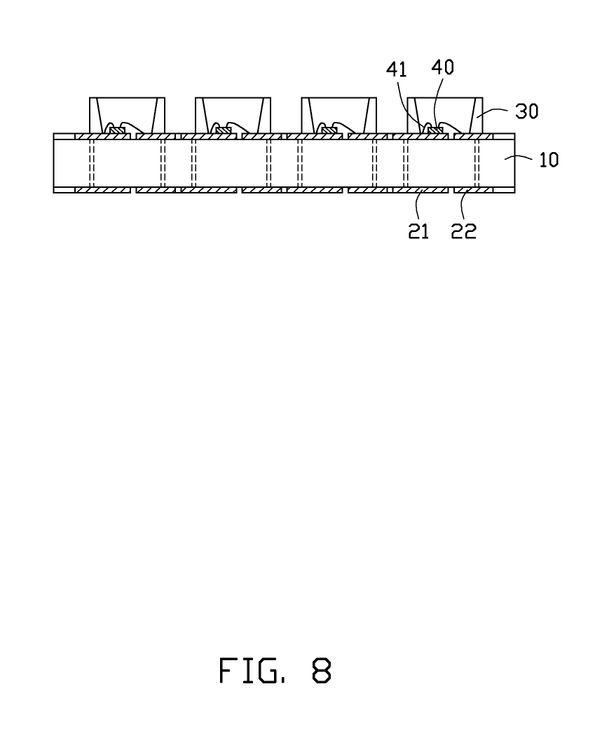

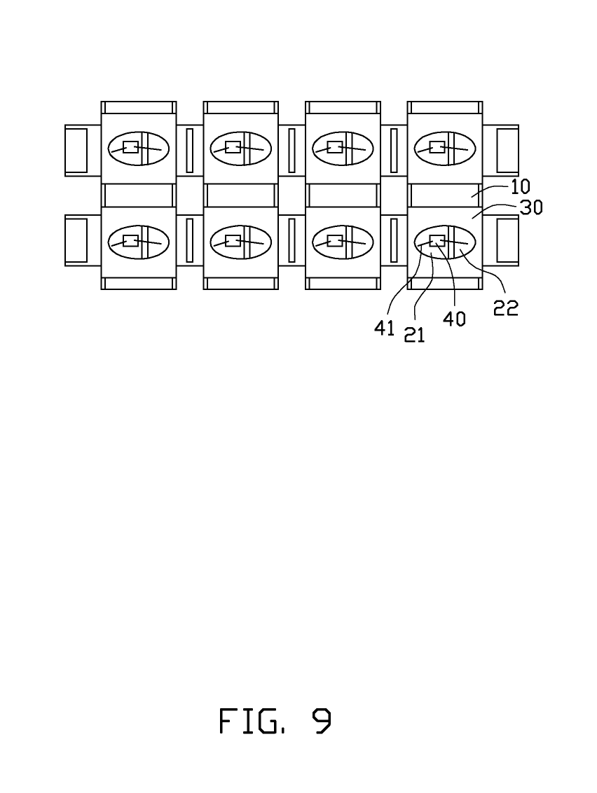

Step 5: as shown in FIGS. 8-9, the light-emitting diode chip 40 is deposed in the reflective cup 31, and is electrically connected to the 1 first electrode 21 and the second electrode 22 by wire binding technology. In the embodiment, the light-emitting diode chip 40 is electrically connected to the first electrode 21 and the second electrode 22 by gold wires 41.

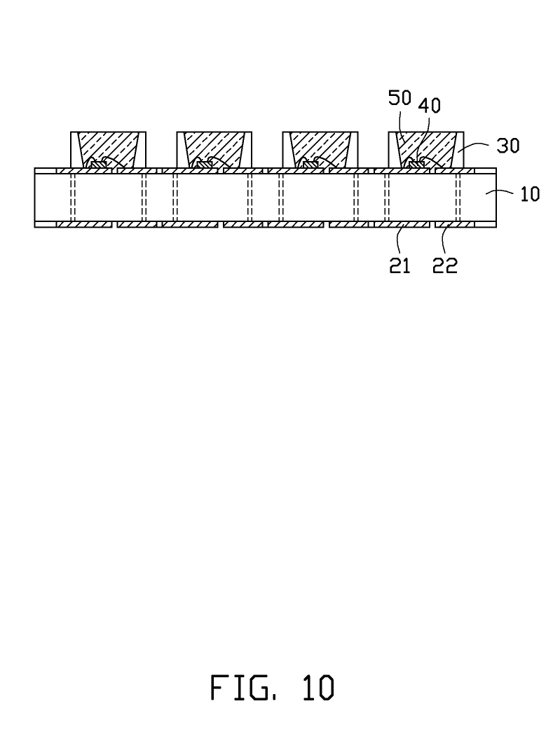

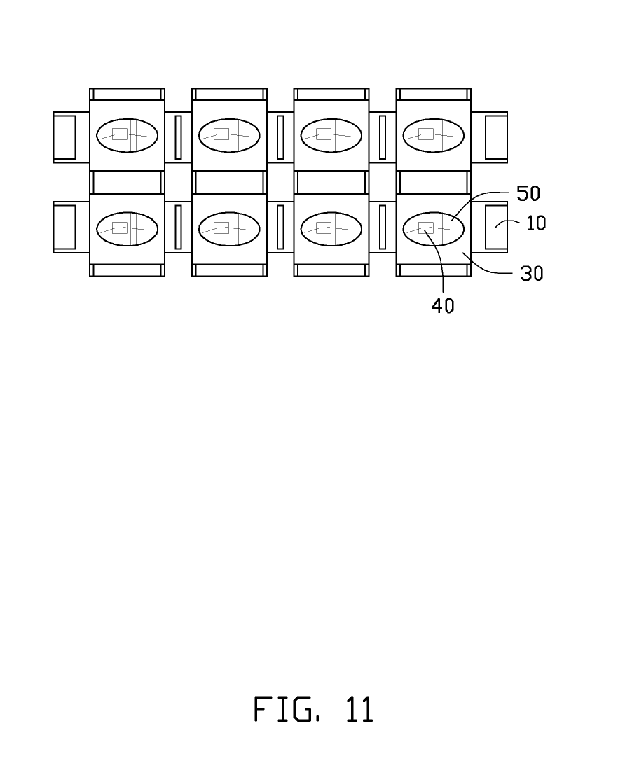

Step 6: as shown in FIGS. 10-11, it includes forming a packaging layer 50 to overlay on the light-emitting diode chip 40. Each reflective cup 31 is corresponding to a packaging layer 50, and the packaging layer 50 fill the reflective cup 31. The packaging layer 50 can further comprise fluorescence powder.

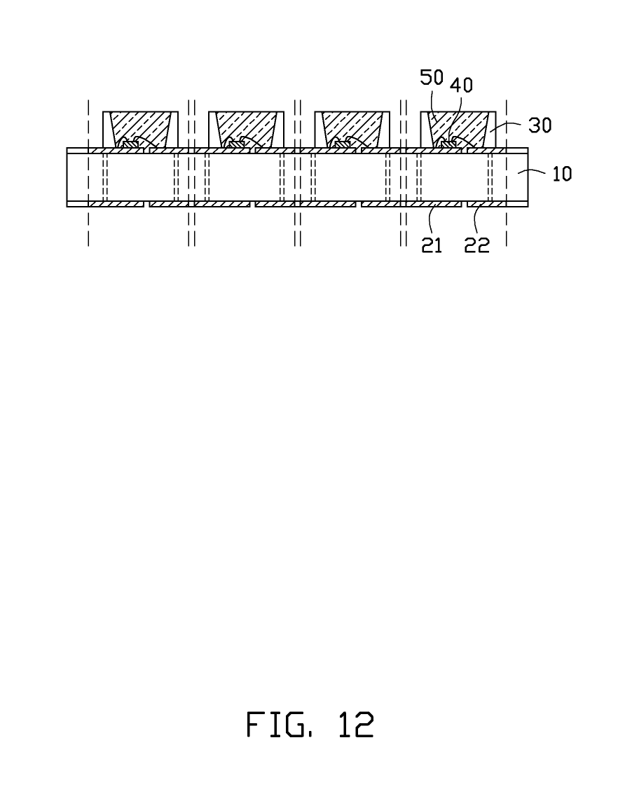

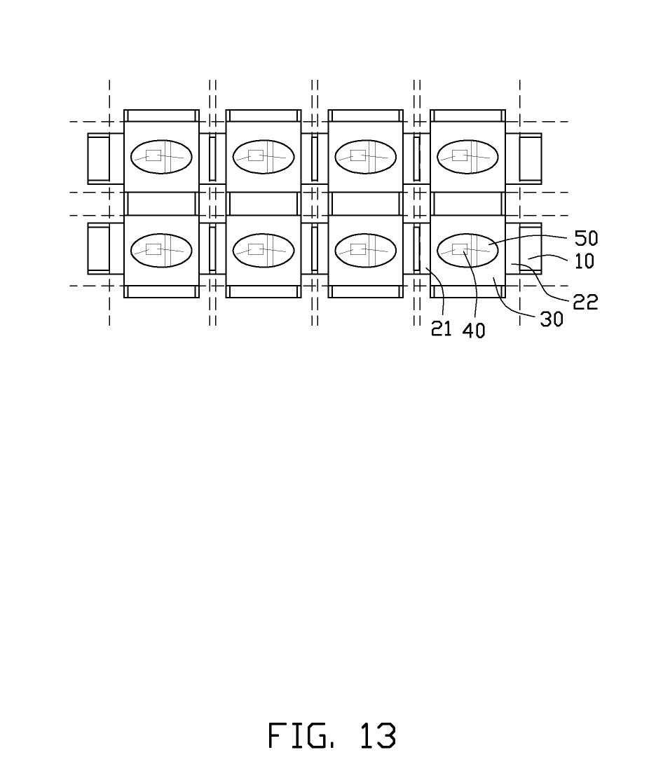

Step 7: as shown in FIGS. 12-13, it includes cutting the substrate 10 to separate each region 200 of the substrate 10 into a light emitting diode 100.

It is possible that the substrate 10 comprises only one region 200 which is described in step 2; therefore the substrate 10 can directly form the electrode group 20 by using the process of step 3. Meanwhile, the cutting process of step 7 can be eliminated.

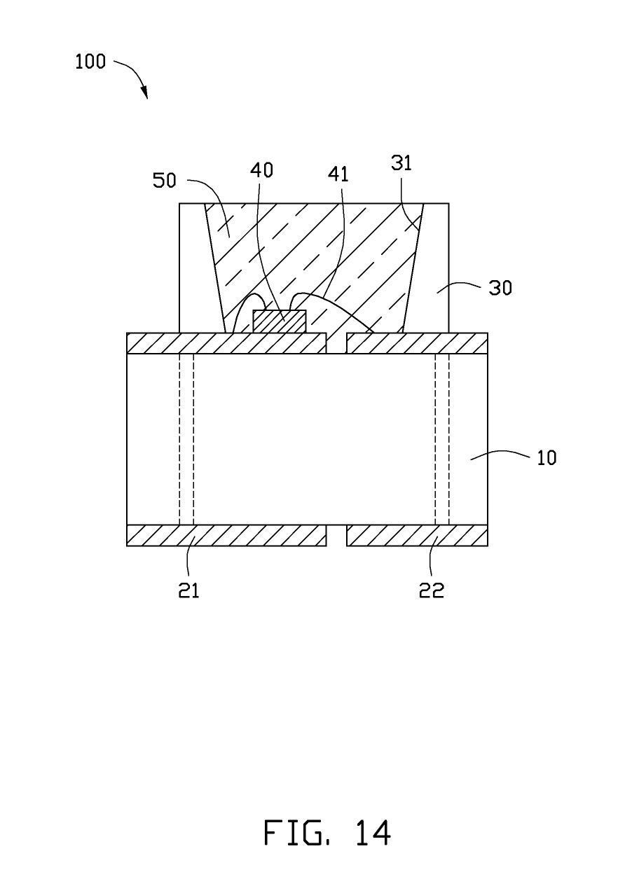

Referring to the FIG. 14, it shows the schematic diagram of the light-emitting diode 100 which is manufactured by the above-mentioned method. The light-emitting diode 100 comprises: a first electrode 21, a second electrode 22 which are electrically insulated from each other, a reflective layer 30, a light-emitting diode 40 and a packaging layer 50. The substrate 10 is a rectangle plate with one square notch in each corner of the substrate 10. The first electrode 21 and the second electrode 22 are separately extended from the top surface to the bottom surface of the substrate 10 through the corresponding four square notches of the substrate 10. In other words, the side surfaces of the four square notches in the four corners of the substrate 10 are correspondingly overlaid by the first electrode 21 and the second electrode 22. The reflective layer 30 is positioned on the top surface of the substrate 10, and it forms a reflective cup 31. The light-emitting diode chip 40 is positioned in the reflective cup 31. The packaging layer 50 overlays on the light-emitting diode chip 40 and fills the reflective cup 31. In the embodiment, the light-emitting diode 100 also comprises wires 41. The light-emitting diode chip 40 electrically connects with the first electrode 21 and the second electrode 22 by the wires 41.

Since the first electrode 21 and the second electrode 22 extend to the top surface, the bottom surface and the side surface of the substrate 10 of the light-emitting diode 100, the light-emitting diode 100 can electrically connect the external power by the bottom surface of the substrate 10 thereof, whereby the light-emitting diode 100 is a top view LED. Or, the light-emitting diode 100 can electrically connect the external power by the side surface of the substrate 10 thereof, whereby the light-emitting diode 100 is a side view LED.

What is claimed is:

1. A manufacturing method of a light-emitting diode, comprising the steps of:
providing a substrate made of ceramic, wherein the substrate defines a plurality of via holes through a top surface and a bottom surface thereof, each four adjacent via holes define a region wherein the four adjacent holes being located at four corners of the region, whereby the substrate defines a plurality of regions;
forming an electrode group on each region, each electrode group being made of metal and including a first electrode and a second electrode which is spaced from the first electrode, and the first electrode and the second electrode both extending from the top surface of each region of the substrate to the bottom surface of each region of the substrate through the four adjacent via holes, the first electrode being through two of the four adjacent via holes and the second electrode being through the other two of the four adjacent via holes;
co-firing the substrate with the electrode group;
forming a reflective cup in each region, each reflective cup overlaying on a part of the first electrode and a pan of the second electrode in a corresponding region;
deposing a light-emitting diode chip in each reflective cup, and electrically connecting the light-emitting diode chip to the first and second electrodes of the electrode group;
overlaying a packaging layer on the light-emitting diode chip; and
cutting the substrate to separate the regions from each other to form a plurality of light-emitting diodes wherein each light-emitting diode includes a corresponding light-emitting diode chip.

2. The manufacturing method of a light-emitting diode as claimed in claim 1, wherein the electrode group is formed on the substrate by direct plating copper on the substrate.

3. The manufacturing method of a light-emitting diode as claimed in claim 1, wherein the substrate is made of alumina or alumina containing ceramic material.

4. The manufacturing method of a light-emitting diode as claimed in claim 1, wherein the shape of each via hole is square, and a width of each via hole is smaller than a distance between two adjacent via holes.

5. The manufacturing method of a light-emitting diode as claimed in claim 1, wherein the reflective cup is formed on the substrate by epoxy resin molding technique.

6. A light-emitting diode, comprising:
a ceramic substrate;
an electrode group attached on the substrate; and
a light-emitting diode deposed on the substrate and electrically connected to the electrode group;
wherein the light-emitting diode is characterized of: the electrode group comprising a first electrode and a second electrode which space from each other, and the first electrode and the second electrode both extend from a top surface of the substrate to a bottom surface of the substrate via side surfaces of the substrate.

7. The light-emitting diode as claimed in claim 6, wherein on the four corners of the substrate are respectively formed with four notches, the first electrode and the second electrode both extend from the top surface to the bottom surface of the substrate through the notches, the side surfaces of the two of the notches of the substrate are correspondingly overlaid by the first electrode and the side surfaces of the other two of the notches of the substrate are correspondingly overlaid by the second electrode.
